(19) United States
(12) Patent Application Publication
(10) Pub. No.: US 2024/0038884 A1
(43) Pub. Date: Feb. 1, 2024

(54) NITRIDE SEMICONDUCTOR DEVICE

(71) Applicant: ROHM CO., LTD., Kyoto-shi (JP)

(72) Inventor: Keita SHIKATA, Kyoto-shi (JP)

(73) Assignee: ROHM CO., LTD., Kyoto-shi (JP)

(21) Appl. No.: 18/482,024

(22) Filed: Oct. 6, 2023

Related U.S. Application Data
(63) Continuation of application No. PCT/JP2022/015092, filed on Mar. 28, 2022.

(30) Foreign Application Priority Data
Apr. 8, 2021 (JP) 2021-065663

(51) Int. Cl. H01L 29/778; H01L 29/20; H01L 29/417

(52) U.S. Cl. CPC H01L 29/7786; H01L 29/2003; H01L 29/41766

(57) ABSTRACT

A nitride semiconductor device 1 includes an SiC substrate 2 of a hexagonal crystal system that has a first main surface 2a and a second main surface 2b at an opposite side thereof and a nitride epitaxial layer 20 that is formed on the first main surface 2a and the first main surface 2a has an off angle of greater than 1° with respect to a c-plane of the hexagonal crystal.

### CROSS-REFERENCE TO RELATED APPLICATIONS

The present application is a bypass continuation of International Patent Application No. PCT/JP2022/015092, filed on Mar. 28, 2022, which corresponds to Japanese Patent Application No. 2021-065663 filed on Apr. 8, 2021 with the Japan Patent Office, and the entire disclosure of this application is incorporated herein by reference.

### TECHNICAL FIELD

The present disclosure relates to a nitride semiconductor device that is constituted of a group III nitride semiconductor (hereinafter referred to at times simply as “nitride semiconductor”).

### BACKGROUND ART

A group III nitride semiconductor is a semiconductor among group III-V semiconductors with which nitrogen is used as the group V element. Aluminum nitride (AlN), gallium nitride (GaN), and indium nitride (InN) are representative examples thereof. It can generally be expressed as AlₓIn_{y}Ga_{1-x-y}N (0≤x≤1, 0≤y≤1, 0≤x+y≤1).

An HEMT (high electron mobility transistor) using a nitride semiconductor is disclosed in Japanese Patent Application Publication No. 2004-363563. The HEMT of Japanese Patent Application Publication No. 2004-363563 includes a p-type Si substrate, a buffer layer formed on the p-type Si substrate, an electron transit layer constituted of GaN and formed on the buffer layer, and an electron supply layer constituted of AlGaN and formed on the electron transit layer. A drain electrode and a gate electrode are formed such as to contact the electron supply layer.

Also, a source electrode is formed such as to penetrate through the electron supply layer, the electron transit layer, and the buffer layer and contact the p-type Si substrate. A rear surface electrode that is electrically connected to the source electrode via the p-type Si substrate is formed on a rear surface of the p-type Si substrate.

Due to polarization caused by lattice mismatch of GaN and AlGaN, a two-dimensional electron gas is formed at a position inside the electron transit layer that is only a few Å inward from an interface between the electron transit layer and the electron supply layer. A source and a drain are connected to each other with the two-dimensional electron gas as a channel. When the two-dimensional electron gas is interrupted by application of a control voltage to the gate electrode, the source and the drain are interrupted from each other.

The aforementioned as well as yet other objects, features, and effects of the present disclosure will be made clear by the following description of the preferred embodiments made with reference to the accompanying drawings.

### BRIEF DESCRIPTION OF DRAWINGS

FIG. 1 is a sectional view for describing the arrangement of a nitride semiconductor device according to a first preferred embodiment of the present disclosure.

FIG. 2A is a sectional view showing an example of a manufacturing process of the nitride semiconductor device.

FIG. 2B is a sectional view showing a step subsequent to that of FIG. 2A.

FIG. 2C is a sectional view showing a step subsequent to that of FIG. 2B.

FIG. 2D is a sectional view showing a step subsequent to that of FIG. 2C.

FIG. 2E is a sectional view showing a step subsequent to that of FIG. 2D.

FIG. 2F is a sectional view showing a step subsequent to that of FIG. 2E.

FIG. 2G is a sectional view showing a step subsequent to that of FIG. 2F.

FIG. 2H is a sectional view showing a step subsequent to that of FIG. 4G.

FIG. 2I is a sectional view showing a step subsequent to that of FIG. 2H.

FIG. 2J is a sectional view showing a step subsequent to that of FIG. 2I.

FIG. 3 is a sectional view for describing the arrangement of a nitride semiconductor device according to a second preferred embodiment of the present disclosure.

FIG. 4A is a sectional view showing an example of a manufacturing process of the nitride semiconductor device.

FIG. 4B is a sectional view showing a step subsequent to that of FIG. 4A.

FIG. 4C is a sectional view showing a step subsequent to that of FIG. 4B.

FIG. 4D is a sectional view showing a step subsequent to that of FIG. 4C.

FIG. 4E is a sectional view showing a step subsequent to that of FIG. 4D.

FIG. 4F is a sectional view showing a step subsequent to that of FIG. 4E.

### DESCRIPTION OF EMBODIMENTS

A preferred embodiment of the present disclosure provides a nitride semiconductor device including an SiC substrate of a hexagonal crystal system that has a first main surface and a second main surface at an opposite side thereof and a nitride epitaxial layer that is formed on the first main surface and where the first main surface has an off angle of greater than 1° with respect to a c-plane of the hexagonal crystal.

With the preferred embodiment of the present disclosure, the first main surface has the off angle that is inclined at an angle of not less than 1° and not more than 8° in a [11-20] direction with respect to the c-plane of the hexagonal crystal.

With the preferred embodiment of the present disclosure, the first main surface has the off angle that is inclined at an angle of not less than 2° and not more than 6° in a [11-20] direction with respect to the c-plane of the hexagonal crystal.

With the preferred embodiment of the present disclosure, the nitride epitaxial layer includes a first nitride semiconductor layer that constitutes an electron transit layer and a second nitride semiconductor layer that is disposed on the first nitride semiconductor layer, constitutes an electron supply layer, and is higher in bandgap than the first nitride semiconductor layer.

With the preferred embodiment of the present disclosure, a semi-insulating nitride layer that is disposed between the SiC substrate and the first nitride semiconductor layer and with which an acceptor concentration is higher than a donor concentration is included.

With the preferred embodiment of the present disclosure, a buffer layer that is disposed between the SiC substrate and the semi-insulating nitride layer and is constituted of a nitride semiconductor is included.

With the preferred embodiment of the present disclosure, a source electrode, a drain electrode, and a gate electrode that are disposed on the second nitride semiconductor layer, a back electrode that is formed on the second main surface, and a conductive member that penetrates through the nitride epitaxial layer and the SiC substrate and electrically connects the source electrode to the back electrode are included.

With the preferred embodiment of the present disclosure, a source electrode, a drain electrode, and a gate electrode that are disposed on the second nitride semiconductor layer, a back electrode that is formed on the second main surface, and a conductive member that penetrates through the nitride epitaxial layer and electrically connects the source electrode to the SiC substrate are included.

With the preferred embodiment of the present disclosure, the first nitride semiconductor layer is constituted of a GaN layer and the second nitride semiconductor layer is constituted of an AlGaN layer.

With the preferred embodiment of the present disclosure, the first nitride semiconductor layer is constituted of a GaN layer, the second nitride semiconductor layer is constituted of an AlGaN layer, and the semi-insulating nitride layer is constituted of a GaN layer that contains carbon.

With the preferred embodiment of the present disclosure, the first nitride semiconductor layer is constituted of a GaN layer, the second nitride semiconductor layer is constituted of an AlGaN layer, the semi-insulating nitride layer is constituted of a GaN layer that contains carbon, and the buffer layer is constituted of a laminated film of an AlN layer formed on the first main surface and an AlGaN layer that is laminated on the AlN layer.

With the preferred embodiment of the present disclosure, the first nitride semiconductor layer is constituted of a GaN layer, the second nitride semiconductor layer is constituted of an AlGaN layer, the semi-insulating nitride layer is constituted of a GaN layer that contains carbon, and the buffer layer is constituted of an AlN layer or an AlGaN layer.

In the following, preferred embodiments of the present disclosure shall be described in detail with reference to the accompanying drawings.

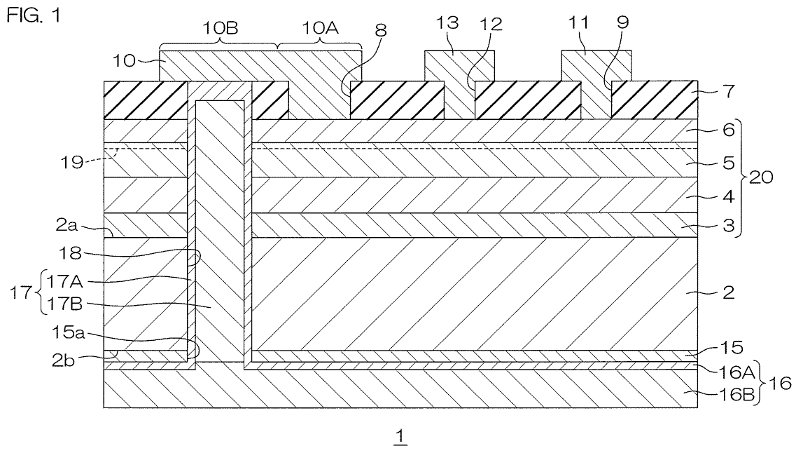

FIG. 1 is a sectional view for describing the arrangement of a nitride semiconductor device according to a first preferred embodiment of the present disclosure.

The nitride semiconductor device 1 includes a substrate 2 that has a first main surface (front surface) 2a and a second main surface (rear surface) 2b at an opposite side thereto and a nitride epitaxial layer 20 that is formed on the first main surface 2a of the substrate 2. The nitride epitaxial layer 20 includes a buffer layer 3 that is formed on the first main surface 2a of the substrate 2, a semi-insulating nitride layer 4 that is formed on the buffer layer 3, a first nitride semiconductor layer 5 that is formed on the semi-insulating nitride layer 4, and a second nitride semiconductor layer 6 that is formed on the first nitride semiconductor layer 5.

Further, the nitride semiconductor device 1 includes an insulating film 7 that is formed on the second nitride semiconductor layer 6. Further, the nitride semiconductor device 1 includes a source electrode 10 and a drain electrode 11 that respectively penetrate through a source contact hole 8 and a drain contact hole 9 formed in the insulating film 7 and are in ohmic contact with the second nitride semiconductor layer 6. The source electrode 10 and the drain electrode 11 are disposed at an interval.

Further, the nitride semiconductor device 1 includes a gate electrode 13 that penetrates through a gate contact hole 12 formed in the insulating film 7 and is in contact with the second nitride semiconductor layer 6. The gate electrode 13 is disposed between the source electrode 10 and the drain electrode 11.

Further, the nitride semiconductor device 1 includes a hard mask layer 15 that is formed on the second main surface 2b of the substrate 2, a back electrode 16 that is formed on a surface of the hard mask layer 15 at an opposite side to the substrate 2, and a contact plug 17 that electrically connects the back electrode 16 and the source electrode 10.

In this preferred embodiment, the substrate 2 is constituted of an SiC substrate of a hexagonal crystal system. In this preferred embodiment, the substrate 2 is an SiC substrate with electrical conductivity. Also, in this preferred embodiment, the substrate 2 is a 4H—SiC substrate.

Also, in this preferred embodiment, the first main surface 2a of the substrate 2 has an off angle of greater than 1° with respect to a c-plane of the hexagonal crystal. More specifically, the first main surface 2a of the substrate 2 has the off angle that is inclined at an angle of not less than 1° and not more than 8° in a [11-20] direction with respect to the c-plane of the hexagonal crystal. The off angle in the [11-20] direction is more preferably not less than 2° and not more than 6° and even more preferably not less than 3° and not more than 5°. In this preferred embodiment, the off angle in the [11-20] direction is approximately 4°. A thickness of the substrate 2 is, for example, approximately 30 μm to 300 μm. In this preferred embodiment, the thickness of the substrate 2 is approximately 150 μm.

The buffer layer 3 is a buffer layer that buffers strain resulting from mismatch of a lattice constant of the semi-insulating nitride layer 4 formed on the buffer layer 3 and a lattice constant of the substrate 2. In this preferred embodiment, the buffer layer 3 is constituted of a multilayer buffer layer in which a plurality of nitride semiconductor films are laminated. In this preferred embodiment, the buffer layer 3 is constituted of a laminated film of an AlN film in contact with the front surface of the substrate 2 and an AlGaN film laminated on a front surface (surface at an opposite side to the substrate 2) of the AlN film. The buffer layer 3 may instead be constituted of a single film of an AlN film or a single film of an AlGaN. A thickness of the buffer layer 3 is, for example, approximately 3 μm to 15 μm. In this preferred embodiment, the thickness of the buffer layer 3 is approximately 5 μm.

The semi-insulating nitride layer 4 is provided to suppress a leak current. The semi-insulating nitride layer 4 is constituted of a GaN layer that is doped with an impurity and a thickness thereof is approximately 1 μm to 10 μm. In this preferred embodiment, the thickness of the semi-insulating nitride layer 4 is approximately 2 μm. The impurity is, for example, C (carbon) and is doped such that a difference between an acceptor concentration Na and a donor concentration Nd (Na−Nd) is approximately 1×10¹⁷ cm⁻³.

The first nitride semiconductor layer 5 constitutes an electron transit layer. In this preferred embodiment, the first nitride semiconductor layer 5 is constituted of an n-type GaN layer that is doped with a donor type impurity and a thickness thereof is approximately 0.05 μm to 1 μm. In this preferred embodiment, the thickness of the first nitride semiconductor layer 5 is approximately 1 μm. Also, the first nitride semiconductor layer 5 may be constituted of an undoped GaN layer instead.

The second nitride semiconductor layer 6 constitutes an electron supply layer. The second nitride semiconductor layer 6 is constituted of a nitride semiconductor of greater bandgap than the first nitride semiconductor layer 5. Specifically, the second nitride semiconductor layer 6 is constituted of a nitride semiconductor of higher Al composition than the first nitride semiconductor layer 5. In a nitride semiconductor, the higher the Al composition, the greater the bandgap. In this preferred embodiment, the second nitride semiconductor layer 6 is constituted of an Alₓ₁Ga₁₋ₓ₁N layer (0<x1≤1) and a thickness thereof is approximately 1 nm to 100 nm. In this preferred embodiment, the thickness of the second nitride semiconductor layer 6 is approximately 20 nm and x1=0.2.

The first nitride semiconductor layer 5 (electron transit layer) and the second nitride semiconductor layer 6 (electron supply layer) are thus constituted of nitride semiconductors that differ in bandgap (Al composition) and a lattice mismatch occurs therebetween. Also, due to spontaneous polarizations of the first nitride semiconductor layer 5 and the second nitride semiconductor layer 6 and a piezo polarization due to the lattice mismatch between the two, an energy level of a conduction band of the first nitride semiconductor layer 5 at an interface between the first nitride semiconductor layer 5 and the second nitride semiconductor layer 6 is made lower than a Fermi level. Thereby, inside the first nitride semiconductor layer 5, a two-dimensional electron gas (2DEG) 19 spreads at a position close to the interface of the first nitride semiconductor layer 5 and the second nitride semiconductor layer 6 (for example, at a distance of only several Å from the interface).

The insulating film 7 is formed across substantially an entire area of a front surface of the second nitride semiconductor layer 6. In this preferred embodiment, the insulating film 7 is constituted of SiN. A thickness of the insulating film 7 is, for example, approximately 10 nm to 200 nm. In this preferred embodiment, the thickness of the insulating film 7 is approximately 100 nm. Besides SiN, the insulating film 7 may be constituted of SiO₂, SiN, SiON, Al₂O₃, AlN, AlON, HfO, HfN, HfON, HfSiON, AlON, etc.

The source electrode 10 includes a main electrode portion 10A and an extension portion 10B. The main electrode portion 10A covers the source contact hole 8 and the peripheral edge portion of the source contact hole 8 at the insulating film 7 front surface. A portion of the main electrode portion 10A enters into the source contact hole 8 and contacts the front surface of the second nitride semiconductor layer 6 inside the source contact hole 8. The extension portion 10B extends along the front surface of the insulating film 7 in a direction opposite to the gate electrode 13 from a side edge of the main electrode portion 10 at an opposite side to the gate electrode 13 side.

The drain electrode 11 covers the drain contact hole 9 and a peripheral edge portion of the drain contact hole 9 at an insulating film 7 front surface. A portion of the drain electrode 11 enters into the drain contact hole 9 and contacts the front surface of the second nitride semiconductor layer 6 inside the drain contact hole 9.

The source electrode 10 and the drain electrode 11 are each constituted, for example, of a Ti/Al laminated film in which a Ti film and an Al film are laminated in that order from a lower layer. A thickness of the Ti film at the lower layer side is, for example, approximately 20 nm and a thickness of the Al film at an upper layer side is, for example, approximately 300 nm.

The source electrode 10 and the drain electrode 11 suffices to be constituted of a material with which ohmic contact can be established with respect to the second nitride semiconductor layer 6 (AlGaN layer). The source electrode 10 and the drain electrode 11 may each be constituted of a Ti/Al/Ni/Au laminated film in which a Ti film, an Al film, an Ni film, and an Au film are laminated in that order from a lower layer.

The gate electrode 13 covers the gate contact hole 12 and a peripheral edge portion of the gate contact hole 12 at the insulating film 7 front surface. A portion of the gate electrode 13 enters into the gate contact hole 12 and contacts the front surface of the second nitride semiconductor layer 6 inside the gate contact hole 12.

The gate electrode 13 is constituted, for example, of an Ni/Au laminated film in which an Ni film and an Au film are laminated in that order from a lower layer. A thickness of the Ni film at the lower layer side is, for example, approximately 10 nm and a thickness of the Au film at an upper layer side is, for example, approximately 600 nm. The gate electrode 13 suffices to be constituted of a material with which a Schottky barrier can be formed with respect to the second nitride semiconductor layer 6 (AlGaN layer).

The hard mask layer 15 is constituted, for example, of an Ni layer and a thickness thereof is, for example, approximately 3 μm. At a position facing a portion of the extension portion 10B of the source electrode 10, the hard mask layer 15 has formed therein an opening portion 15a that penetrates through the hard mask layer 15 in a thickness direction.

A back contact hole 18 that is in communication with the opening portion 15a of the hard mask layer 15 and penetrates continuously through the substrate 2, the nitride epitaxial layer 20, and the insulating film 7 is formed between the second main surface 2b of the substrate 2 and the extension portion 10B of the source electrode 10. A contact plug (conductor) 17, an upper end of which is connected to the source electrode 10 on the insulating film 7, is embedded in the opening portion 15a and the back contact hole 18.

The contact plug 17 is constituted of a barrier metal film 17A and a metal plug 17B. The barrier metal film 17A is formed such as to cover side surfaces of the opening portion 15a, side surfaces of the back contact hole 18, and a bottom surface of the back contact hole 18 (a region of a lower surface of the extension portion 10B of the source electrode 10 that faces the back contact hole 18). The metal plug 17B is embedded in the opening portion 15a and the back contact hole 22 in a state of being surrounded by the barrier metal film 17A. The barrier metal film 17A is constituted, for example, of TiN. The metal plug 17B is constituted, for example, of Au. The metal plug 17B may instead be constituted of Cu.

The contact plug 17 is an example of a “conductive member that electrically connects the source electrode to the back electrode” of the present disclosure.

The back electrode 16 is formed on the surface of the hard mask layer 15 at the opposite side to the substrate 2 such as to cover the surface and a lower end surface of the contact plug 17. The back electrode 16 is constituted of a barrier metal film 16A that is formed on the surface of the hard mask layer 15 at the opposite side to the substrate 2 and an electrode metal 16B that is formed on a surface of the barrier metal film 16A at an opposite side to the hard mask layer 15 such as to cover the surface and the lower end surface of the contact plug 17.

The barrier metal film 16A is constituted, for example, of TiN. The electrode metal 16B is constituted, for example, of Au. The electrode metal 16B may instead be constituted of Cu. In this preferred embodiment, the barrier metal film 16A is formed integral to the barrier metal film 17A and the electrode metal 16B is formed integral to metal plug 17B.

The back electrode 16 is electrically connected to the source electrode 10 via the contact plug 17.

With the nitride semiconductor device 1, a heterojunction is formed by there being formed, on the first nitride semiconductor layer 5 (electron transit layer), the second nitride semiconductor layer 6 that differs in bandgap (Al composition). Thereby, the two-dimensional electron gas 19 is formed inside the first nitride semiconductor layer 5 near the interface of the first nitride semiconductor layer 5 and the second nitride semiconductor layer 6 and an HEMT that uses the two-dimensional electron gas 19 as a channel is formed.

In a state where a control voltage is not applied to the gate electrode 13, the source electrode 10 and the drain electrode 11 are electrically connected to each other with the two-dimensional electron gas 19 as the channel. Therefore, the HEMT is of a normally-on type. When the control voltage such that a potential at the gate electrode 13 is made negative with respective to the source electrode 10 is applied to the gate electrode 13, the two-dimensional electron gas 19 is interrupted and the HEMT is put in an off state.

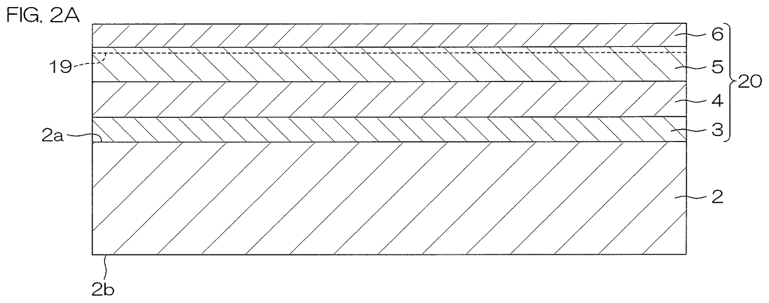

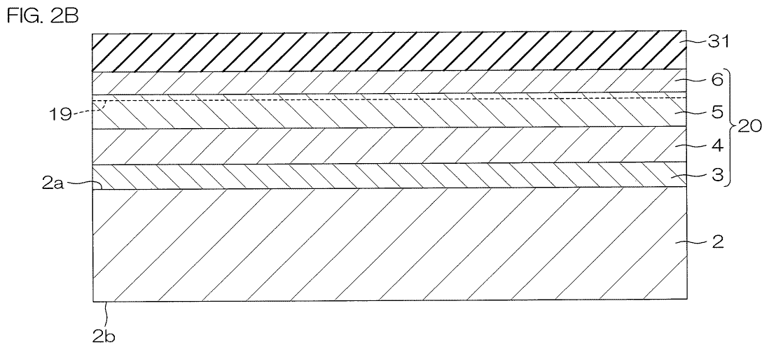

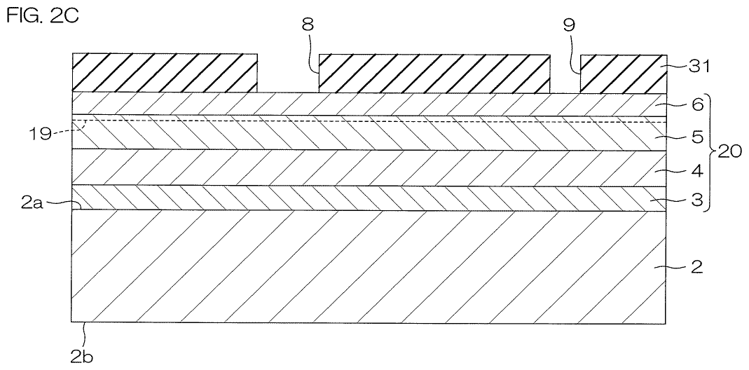

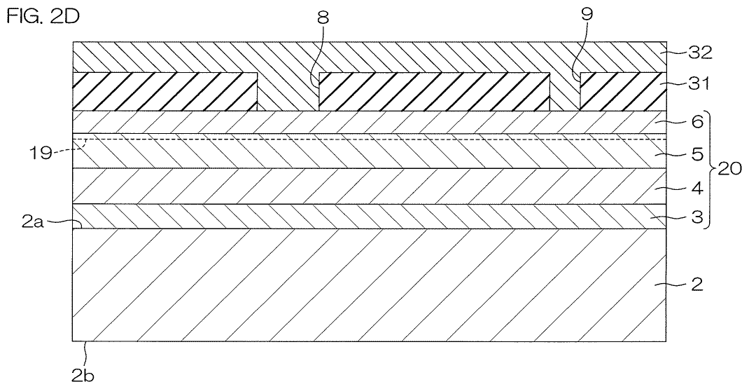

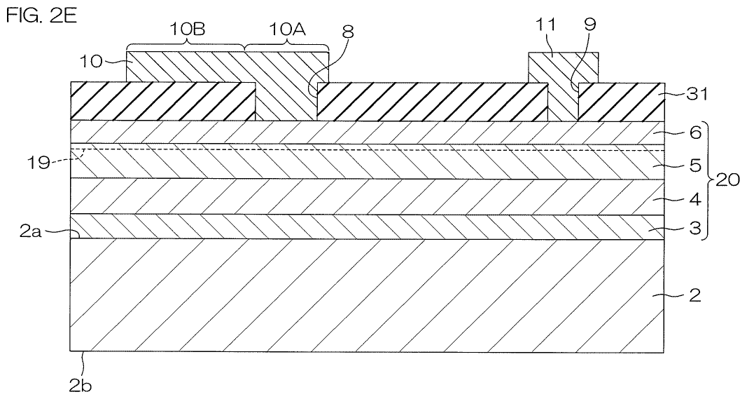

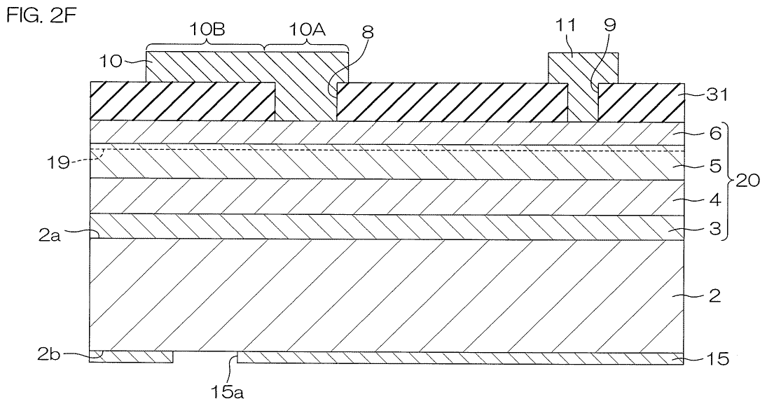

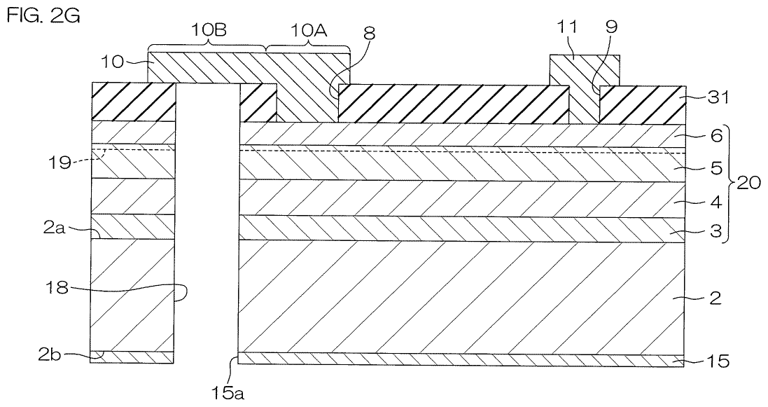

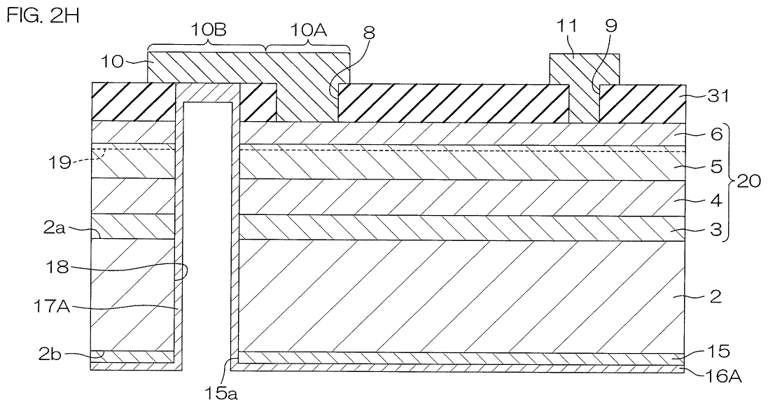

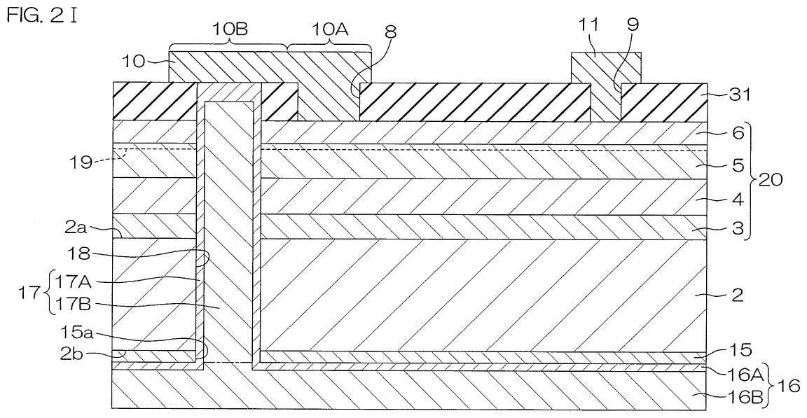

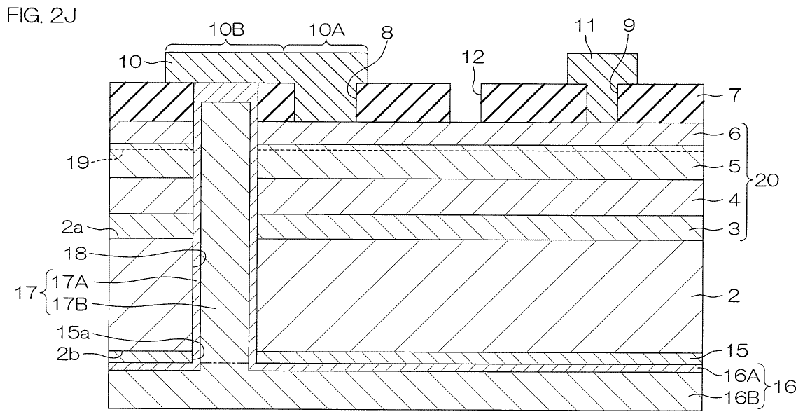

FIG. 2A to FIG. 2J are sectional views for describing an example of a manufacturing process of the nitride semiconductor device 1 described above and show a sectional structure in a plurality of stages of the manufacturing process.

First, as shown in FIG. 2A, the buffer layer 3 and the semi-insulating nitride layer 4 are epitaxially grown successively on the first main surface 2a of the substrate 2, for example, by an MOCVD (metal organic chemical vapor deposition) method. Further, the first nitride semiconductor layer (electron transit layer) 5 and the second nitride semiconductor layer (electron supply layer) 6 are epitaxially grown successively on the semi-insulating nitride layer 4 by the MOCVD method. The nitride epitaxial layer 20 constituted of the buffer layer 3, the semi-insulating nitride layer 4, the first nitride semiconductor layer 5, and the second nitride semiconductor layer 6 is thereby formed on the first main surface 2a of the substrate 2.

Next, as shown in FIG. 2B, by a plasma CVD method, LPCVD (low pressure CVD) method, MOCVD method, sputtering method, etc., an insulating material film 31 that is a material film of the insulating film 7 is formed on the second nitride semiconductor layer 6.

Next, a resist film (not shown) is formed on the insulating material film 31 in a region excluding regions in which the source contact hole 8 and the drain contact hole 9 are to be formed. By the insulating material film 31 being dry etched via the resist film, the source contact hole 8 and the drain contact hole 9 are formed in the insulating material film 31 as shown in FIG. 2C. The source contact hole 8 and the drain contact hole 9 penetrate through the insulating material film 31 and reach the second nitride semiconductor layer 6. As the etching gas, for example, CF₄ gas is used. Thereafter, the resist film is removed.

Next, as shown in FIG. 2D, for example, by an electron beam vapor deposition method, sputtering method, etc., an electrode film 32 that is a material film of the source electrode 10 and the drain electrode 11 is formed on the second nitride semiconductor layer 6 such as to cover the insulating material film 31. The electrode film 32 is constituted, for example, of a Ti/Al laminated film in which a Ti film and an Al film are laminated in that order from a lower layer.

A resist film that covers a source electrode preparation planned region and a drain electrode preparation planned region of a front surface of the electrode film 32 is formed. By the electrode film 32 then being etched selectively using the resist film as a mask, the source electrode 10 including the main electrode portion 10A and the extension portion 10B and the drain electrode 11 are obtained as shown in FIG. 2E.

Next, as shown in FIG. 2F, after the resist film is removed, the hard mask layer 15 having the opening portion 15a is formed on the second main surface 2b of the substrate 2. The hard mask layer 15 having the opening portion 15a is prepared by forming an Ni film, for example, by a sputtering method on the second main surface 2b of the substrate 2 and thereafter patterning the Ni film, for example, by an ion milling method.

Next, as shown in FIG. 2G, the substrate 2, the nitride epitaxial layer 20, and the insulating material film 31 are dry etched using the hard mask layer 15 as a mask to form the back contact hole 18 that penetrates through the substrate 2, the nitride epitaxial layer 20, and the insulating material film 31. In this process, the lower surface of the extension portion 10B of the source electrode 10 functions as an etching stopper layer. As the etching gas, for example, SF₆ gas is used.

Next, as shown in FIG. 2H, a material film (for example, a TiN film) of the barrier metal films 16A and 17A is formed, for example, by a sputtering method on the side surfaces and the bottom surface (a portion of the lower surface of the extension portion 10B of the source electrode 10) of the back contact hole 18, the side surfaces of the opening portion 15a, and the surface of the hard mask layer 15 at the opposite side to the substrate 2. The barrier metal film 17A is thereby formed on the side surfaces and the bottom surface of the back contact hole 18 and the side surfaces of the opening portion 15a and the barrier metal film 16A is formed on the surface of the hard mask layer 15 at the opposite side to the substrate 2.

Next, as shown in FIG. 2I, a film of gold (Au) is formed on the barrier metal film 17A and the barrier metal film 16A, for example, by a plating method. Thereby, the metal plug 17B that is surrounded by the barrier metal film 17A is formed inside the back contact hole 18 and the electrode metal 16B is formed on the barrier metal film 16A. The contact plug 17 constituted of the barrier metal film 17A and the metal plug 17B and the back electrode 16 constituted of the barrier metal film 16A and the electrode metal 16B are thereby obtained.

Next, on the insulating material film 31, the source electrode 10, and the drain electrode 11, a resist film (not shown) is formed in a region excluding a region in which the gate contact hole 12 is to be formed. By the insulating material film 31 being dry etched via the resist film, the gate contact hole 12 is formed in the insulating material film 31 as shown in FIG. 2J. As the etching gas, for example, CF₄ gas is used. Thereby, the insulating material film 31 is patterned and the insulating film 7 is obtained. The gate contact hole 12 penetrates through the insulating film 7 and reaches the second nitride semiconductor layer 6.

Next, after removing the resist film, the gate electrode 13 is formed and the nitride semiconductor device 1 such as shown in FIG. 1 is thereby obtained. The gate electrode 13 is constituted, for example, of the Ni/Au laminated film in which the Ni film and the Au film are laminated in that order from the lower layer.

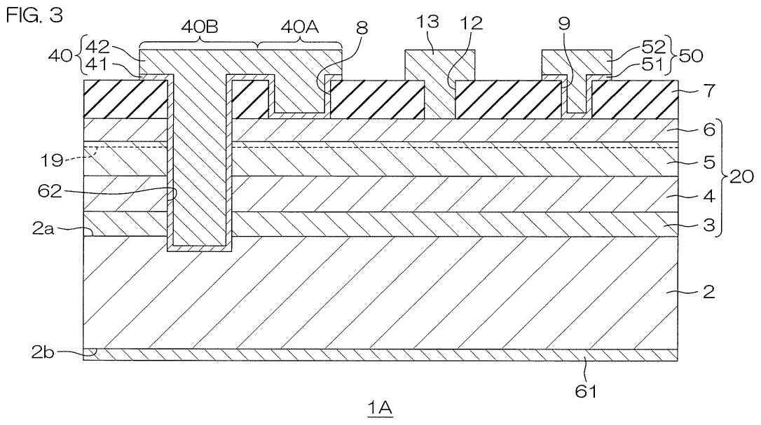

FIG. 3 is a sectional view for describing the arrangement of a nitride semiconductor device according to a second preferred embodiment of the present disclosure.

The nitride semiconductor device 1A includes the substrate 2 that has the first main surface (front surface) 2a and the second main surface (rear surface) 2b at the opposite side thereto and the nitride epitaxial layer 20 that is formed on the first main surface 2a of the substrate 2. The nitride epitaxial layer 20 includes the buffer layer 3 that is formed on the first main surface 2a of the substrate 2, the semi-insulating nitride layer 4 that is formed on the buffer layer 3, the first nitride semiconductor layer 5 that is formed on the semi-insulating nitride layer 4, and the second nitride semiconductor layer 6 that is formed on the first nitride semiconductor layer 5.

Further, the nitride semiconductor device 1A includes the insulating film 7 that is formed on the second nitride semiconductor layer 6. Further, the nitride semiconductor device 1A includes a source electrode 40 and a drain electrode 50 that penetrate through the source contact hole 8 and the drain contact hole 9 formed in the insulating film 7 and are in ohmic contact with the second nitride semiconductor layer 6. The source electrode 40 and the drain electrode 50 are disposed at an interval.

Further, the nitride semiconductor device 1A includes the gate electrode 13 that penetrates through the gate contact hole 12 formed in the insulating film 7 and is in contact with the second nitride semiconductor layer 6. The gate electrode 13 is disposed between the source electrode 40 and the drain electrode 50. Further, the nitride semiconductor device 1A includes a back electrode 61 that is formed on the second main surface 2b of the substrate 2.

In this preferred embodiment, the substrate 2 is constituted of an SiC substrate of a hexagonal crystal system. In this preferred embodiment, the substrate 2 is an SiC substrate with electrical conductivity. Also, in this preferred embodiment, the substrate 2 is a 4H—SiC substrate.

Also, in this preferred embodiment, the first main surface 2a of the substrate 2 has an off angle of greater than 1° with respect to a c-plane of the hexagonal crystal. More specifically, the first main surface 2a of the substrate 2 has the off angle that is inclined at an angle of not less than 1° and not more than 8° in a [11-20] direction with respect to the c-plane of the hexagonal crystal. The off angle in the [11-20] direction is more preferably not less than 2° and not more than 6° and even more preferably not less than 3° and not more than 5°. In this preferred embodiment, the off angle in the [11-20] direction is approximately 4°. A thickness of the substrate 2 is, for example, approximately 30 μm to 300 μm. In this preferred embodiment, the thickness of the substrate 2 is approximately 150 μm.

The buffer layer 3 is a buffer layer that buffers strain resulting from mismatch of a lattice constant of the semi-insulating nitride layer 4 formed on the buffer layer 3 and a lattice constant of the substrate 2. In this preferred embodiment, the buffer layer 3 is constituted of a multilayer buffer layer in which a plurality of nitride semiconductor films are laminated. In this preferred embodiment, the buffer layer 3 is constituted of a laminated film of an AlN film in contact with the front surface of the substrate 2 and an AlGaN film laminated on a front surface (surface at an opposite side to the substrate 2) of the AlN film. The buffer layer 3 may instead be constituted of a single film of an AlN film or a single film of an AlGaN. A thickness of the buffer layer 3 is, for example, approximately 3 μm to 15 μm. In this preferred embodiment, the thickness of the buffer layer 3 is approximately 5 μm.

The semi-insulating nitride layer 4 is provided to suppress a leak current. The semi-insulating nitride layer 4 is constituted of a GaN layer that is doped with an impurity and a thickness thereof is approximately 1 μm to 10 μm. In this preferred embodiment, the thickness of the semi-insulating nitride layer 4 is approximately 2 μm. The impurity is, for example, C (carbon) and is doped such that a difference between an acceptor concentration Na and a donor concentration Nd (Na−Nd) is approximately 1×10¹⁷ cm⁻³.

The first nitride semiconductor layer 5 constitutes an electron transit layer. In this preferred embodiment, the first nitride semiconductor layer 5 is constituted of an n-type GaN layer that is doped with a donor type impurity and a thickness thereof is approximately 0.05 μm to 1 μm. In this preferred embodiment, the thickness of the first nitride semiconductor layer 5 is approximately 1 μm. Also, the first nitride semiconductor layer 5 may be constituted of an undoped GaN layer instead.

The second nitride semiconductor layer 6 constitutes an electron supply layer. The second nitride semiconductor layer 6 is constituted of a nitride semiconductor of greater bandgap than the first nitride semiconductor layer 5. Specifically, the second nitride semiconductor layer 6 is constituted of a nitride semiconductor of higher Al composition than the first nitride semiconductor layer 5. In a nitride semiconductor, the higher the Al composition, the greater the bandgap. In this preferred embodiment, the second nitride semiconductor layer 6 is constituted of an Alₓ₁Ga₁₋ₓ₁N layer (0<x1≤1) and a thickness thereof is approximately 1 nm to 100 nm. In this preferred embodiment, the thickness of the second nitride semiconductor layer 6 is approximately 20 nm and x1=0.2.

The first nitride semiconductor layer 5 (electron transit layer) and the second nitride semiconductor layer 6 (electron supply layer) are thus constituted of nitride semiconductors that differ in bandgap (Al composition) and a lattice mismatch occurs therebetween. Also, due to spontaneous polarizations of the first nitride semiconductor layer 5 and the second nitride semiconductor layer 6 and a piezo polarization due to the lattice mismatch between the two, an energy level of a conduction band of the first nitride semiconductor layer 5 at an interface between the first nitride semiconductor layer 5 and the second nitride semiconductor layer 6 is made lower than a Fermi level. Thereby, inside the first nitride semiconductor layer 5, a two-dimensional electron gas (2DEG) 19 spreads at a position close to the interface of the first nitride semiconductor layer 5 and the second nitride semiconductor layer 6 (for example, at a distance of only several Å from the interface).

The insulating film 7 is formed across substantially an entire area of a front surface of the second nitride semiconductor layer 6. In this preferred embodiment, the insulating film 7 is constituted of SiN. A thickness of the insulating film 7 is, for example, approximately 10 nm to 200 nm. In this preferred embodiment, the thickness of the insulating film 7 is approximately 100 nm. Besides SiN, the insulating film 7 may be constituted of SiO₂, SiN, SiON, Al₂O₃, AlN, AlON, HfO, HfN, HfON, HfSiON, AlON, etc.

In the substrate 2, the nitride epitaxial layer 20, and the insulating film 7, a back contact hole 62 penetrating continuously through the insulating film 7 and the nitride epitaxial layer 20 from a front surface of the insulating film 7 and extending to an intermediate thickness of the substrate 2 is formed at an opposite side to the gate contact hole 12 with respect to the source contact hole 8.

The source electrode 40 includes a main electrode portion 40A and an extension portion 40B. The main electrode portion 40A covers the source contact hole 8 and the peripheral edge portion of the source contact hole 8 at the insulating film 7 front surface. A portion of the main electrode portion 40A enters into the source contact hole 8 and contacts the front surface of the second nitride semiconductor layer 6 inside the source contact hole 8.

The extension portion 40B covers the back contact hole 62 and a peripheral edge portion of the back contact hole 62 at the insulating film 7 front surface. A side edge of the extension portion 40B at the main electrode portion 40A side and a side edge of the main electrode portion 40A at the extension portion 10B side are connected. A portion of the extension portion 40B enters into the back contact hole 62 and contacts the substrate 2 inside the back contact hole 62. The extension portion 40B is an example of a “conductive member that electrically connects the source electrode to the SiC electrode” in the present disclosure.

The source electrode 40 is constituted of a barrier metal film 41 and an electrode metal 42 formed on the barrier metal film 41. The barrier metal film 41 covers inner surfaces (side surfaces and bottom surface) of the source contact hole 8, the peripheral edge portion of the back contact hole 62 at the insulating film 7 front surface (side surfaces and bottom surface), inner surfaces of the back contact hole 62, and the peripheral edge portion of the back contact hole 62 at the insulating film 7 front surface. The barrier metal film 41 is constituted, for example, of a TiN film. The electrode metal 42 is constituted, for example, of Au. The electrode metal 42 may instead be constituted of Cu.

The drain electrode 50 covers the drain contact hole 9 and the peripheral edge portion of the drain contact hole 9 at the insulating film 7 front surface. A portion of the drain electrode 50 enters into the drain contact hole 9 and contacts the front surface of the second nitride semiconductor layer 6 inside the drain contact hole 9.

The drain electrode 50 is constituted of a barrier metal film 51 that covers the drain contact hole 9 and the peripheral edge portion of the drain contact hole 9 at the insulating film 7 front surface and an electrode metal 52 formed on the barrier metal film 51. The barrier metal film 51 is constituted, for example, of a TiN film. The electrode metal 52 is constituted, for example, of Au. The electrode metal 52 may instead be constituted of Cu.

The gate electrode 13 covers the gate contact hole 12 and a peripheral edge portion of the gate contact hole 12 at the insulating film 7 front surface. A portion of the gate electrode 13 enters into the gate contact hole 12 and contacts the front surface of the second nitride semiconductor layer 6 inside the gate contact hole 12.

The gate electrode 13 is constituted, for example, of an Ni/Au laminated film in which an Ni film and an Au film are laminated in that order from a lower layer. A thickness of the Ni film at the lower layer side is, for example, approximately 10 nm and a thickness of the Au film at an upper layer side is, for example, approximately 600 nm. The gate electrode 13 suffices to be constituted of a material with which a Schottky barrier can be formed with respect to the second nitride semiconductor layer 6 (AlGaN layer).

The back electrode 61 is formed such as to cover substantially an entire area of the second main surface 2b of the substrate 2. The back electrode 61 is constituted, for example, of an Ni film. The back electrode 61 is electrically connected to the main electrode portion 40A of the source electrode 40 via the substrate 2 and the extension portion 40B of the source electrode 40.

With the nitride semiconductor device 1A, a heterojunction is formed by there being formed, on the first nitride semiconductor layer 5 (electron transit layer), the second nitride semiconductor layer 6 that differs in bandgap (Al composition). Thereby, the two-dimensional electron gas 19 is formed inside the first nitride semiconductor layer 5 near the interface of the first nitride semiconductor layer 5 and the second nitride semiconductor layer 6 and an HEMT that uses the two-dimensional electron gas 19 as a channel is formed.

In a state where a control voltage is not applied to the gate electrode 13, the source electrode 10 and the drain electrode 11 are connected to each other with the two-dimensional electron gas 19 as the channel. Therefore, the HEMT is of a normally-on type. When the control voltage such that a potential at the gate electrode 13 is made negative with respect to the source electrode 10 is applied to the gate electrode 13, the two-dimensional electron gas 19 is interrupted and the HEMT is put in an off state.

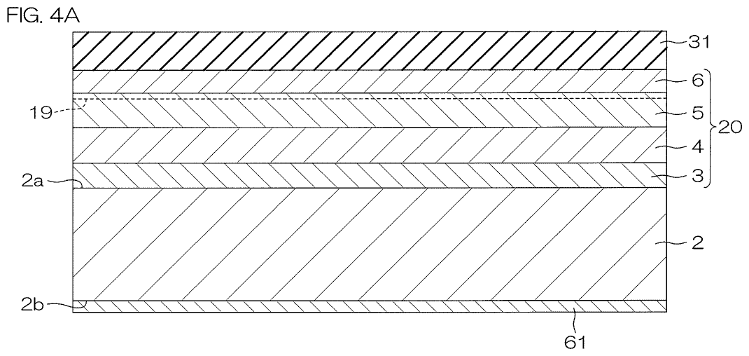

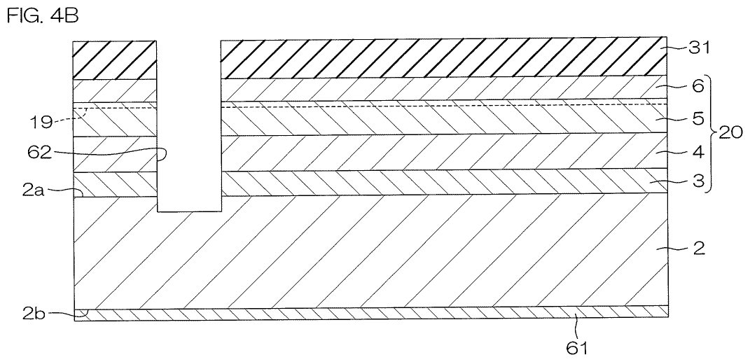

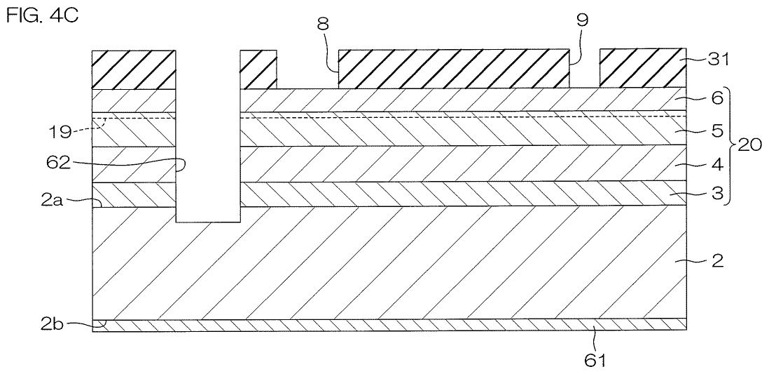

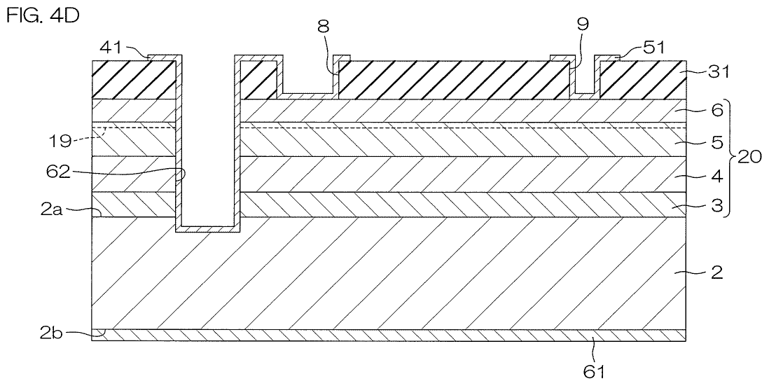

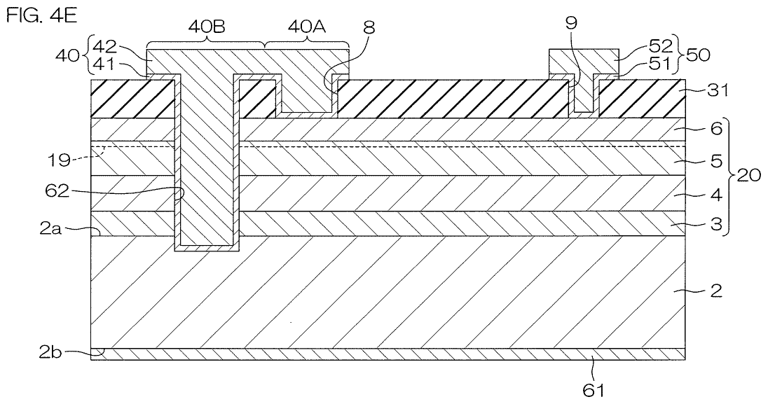

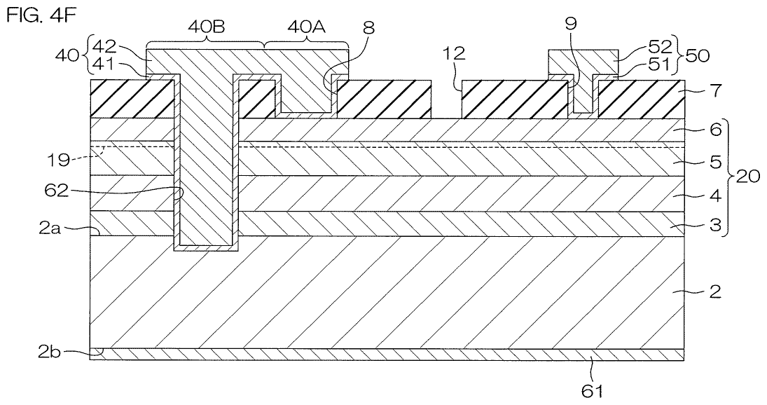

FIG. 4A to FIG. 4J are sectional views for describing an example of a manufacturing process of the nitride semiconductor device 1A described above and show a sectional structure in a plurality of stages of the manufacturing process.

Even in manufacturing the nitride semiconductor device 1A of FIG. 3, the steps shown in FIG. 2A and FIG. 2B are carried out as in manufacturing the nitride semiconductor device 1A of FIG. 1. That is, as shown in FIG. 2A, the buffer layer 3 and the semi-insulating nitride layer 4 are epitaxially grown successively on the first main surface 2a of the substrate 2, for example, by an MOCVD method. Further, the first nitride semiconductor layer (electron transit layer) 5 and the second nitride semiconductor layer (electron supply layer) 6 are epitaxially grown successively on the semi-insulating nitride layer 4 by the MOCVD method. The nitride epitaxial layer 20 constituted of the buffer layer 3, the semi-insulating nitride layer 4, the first nitride semiconductor layer 5, and the second nitride semiconductor layer 6 is thereby formed on the first main surface 2a of the substrate 2.

Next, as shown in FIG. 2B, by the plasma CVD method, LPCVD method, MOCVD method, sputtering method, etc., the insulating material film 31 that is the material film of the insulating film 7 is formed on the second nitride semiconductor layer 6.

Next, as shown in FIG. 4A, the back electrode 61 is formed on the second main surface 2b of the substrate 2. The back electrode 61 is formed by forming an Ni film, for example, by a sputtering method on the second main surface 2b of the substrate 2.

Next, a resist film (not shown) is formed on the insulating material film 31 in a region excluding a region in which the back contact hole 62 is to be formed. By the insulating material film 31, the nitride epitaxial layer 20, and a portion of the substrate 2 being dry etched via the resist film, the back contact hole 62 that penetrates continuously through the insulating material film 31 and the nitride epitaxial layer 20 and reaches an interior of the substrate 2 is formed as shown in FIG. 4B. For etching of the insulating material film 31, for example, CF₄ gas is used, and for etching of the nitride epitaxial layer 20 and the substrate 2, for example, a BCL₃/CL₂ mixed gas is used.

Thereafter, the resist film is removed. Then, a resist film (not shown) is formed on the insulating material film 31 in a region excluding regions in which the source contact hole 8 and the drain contact hole 9 are to be formed. By the insulating material film 31 being dry etched via the resist film, the source contact hole 8 and the drain contact hole 9 are formed in the insulating material film 31 as shown in FIG. 4C. The source contact hole 8 and the drain contact hole 9 penetrate through the insulating material film 31 and reach the second nitride semiconductor layer 6. As the etching gas, for example, CF₄ gas is used.

Next, the resist film is removed. Then, for example, by a sputtering method, a barrier metal material film (for example, a TiN film) that is a material film of the barrier metal films 41 and 51 is formed on the front surface of the insulating material film 31, the inner surfaces (side surfaces and bottom surface) of the back contact hole 62, the inner surfaces of the source contact hole 8, and inner surfaces of the drain contact hole 9. The barrier metal films 41 and 51 are then formed as shown in FIG. 4D by the barrier material film being patterned.

Next, as shown in FIG. 4E, for example, by a plating method, the electrode metal 42 constituted, for example, of Au is formed on the barrier metal 41 and the electrode metal 52 constituted, for example, of Au is formed on the barrier metal 51. The source electrode 40 constituted of the barrier metal film 41 and the electrode metal 42 and the drain electrode 50 constituted of the barrier metal film 51 and the electrode metal 52 are thereby obtained. The source electrode 40 includes the main electrode portion 40A and the extension portion 40B.

Next, on the insulating material film 31, the source electrode 10, and the drain electrode 11, a resist film (not shown) is formed in the region excluding the region in which the gate contact hole 12 is to be formed. By the insulating material film 31 being dry etched via the resist film, the gate contact hole 12 is formed in the insulating material film 31 as shown in FIG. 4F. Thereby, the insulating material film 31 is patterned and the insulating film 7 is obtained. The gate contact hole 12 penetrates through the insulating film 7 and reaches the second nitride semiconductor layer 6. As the etching gas, for example, CF₄ gas is used.

Next, after removing the resist film, the gate electrode 13 is formed and the nitride semiconductor device 1A such as shown in FIG. 3 is thereby obtained. The gate electrode 13 is constituted, for example, of the Ni/Au laminated film in which the Ni film and the Au film are laminated in that order from the lower layer.

Although with each of the first and second preferred embodiments described above, the semi-insulating nitride layer 4 is formed on the buffer layer 3, the semi-insulating nitride layer 4 does not have to be formed.

Also, although with each of the first and second preferred embodiments described above, an example where the first nitride semiconductor layer (electron transit layer) 5 is constituted of a GaN layer and the second nitride semiconductor layer (electron supply layer) 6 is constituted of an AlGaN layer, it suffices that the first nitride semiconductor layer 5 and the second nitride semiconductor layer 6 differ in bandgap (for example, in Al composition) and other combinations are also possible. For example, as combinations of the first nitride semiconductor layer 5/second nitride semiconductor layer 6, GaN/AlN, AlGaN/AlN, etc., can be given as examples.

While preferred embodiments of the present disclosure were described in detail above, these are merely specific examples used to clarify the technical contents of the present disclosure and the present disclosure should not be interpreted as being limited to these specific examples, the scope of the present disclosure is limited only by the appended claims, and various design modifications can be applied within the scope of other matters described in the claims.

1. A nitride semiconductor device comprising:
an SiC substrate of a hexagonal crystal system that has a first main surface and a second main surface at an opposite side thereof; and
a nitride epitaxial layer that is formed on the first main surface; and
wherein the first main surface has an off angle of greater than 1° with respect to a c-plane of the hexagonal crystal.

2. The nitride semiconductor device according to claim 1, wherein the first main surface has the off angle that is inclined at an angle of not less than 1° and not more than 8° in a [11-20] direction with respect to the c-plane of the hexagonal crystal.

3. The nitride semiconductor device according to claim 1, wherein the first main surface has the off angle that is inclined at an angle of not less than 2° and not more than 6° in a [11-20] direction with respect to the c-plane of the hexagonal crystal.

4. The nitride semiconductor device according to claim 1, wherein the nitride epitaxial layer comprises:
a first nitride semiconductor layer that constitutes an electron transit layer and
a second nitride semiconductor layer that is disposed on the first nitride semiconductor layer, constitutes an electron supply layer, and is higher in bandgap than the first nitride semiconductor layer.

5. The nitride semiconductor device according to claim 4, comprising: a semi-insulating nitride layer that is disposed between the SiC substrate and the first nitride semiconductor layer and with which an acceptor concentration is higher than a donor concentration.

6. The nitride semiconductor device according to claim 5, comprising: a buffer layer that is disposed between the SiC substrate and the semi-insulating nitride layer and is constituted of a nitride semiconductor.

7. The nitride semiconductor device according to claim 4, comprising: a source electrode; a drain electrode; and a gate electrode that are disposed on the second nitride semiconductor layer;
a back electrode that is formed on the second main surface; and
a conductive member that penetrates through the nitride epitaxial layer and the SiC substrate and electrically connects the source electrode to the back electrode.

8. The nitride semiconductor device according to claim 4, comprising: a source electrode; a drain electrode; and a gate electrode that are disposed on the second nitride semiconductor layer;
a back electrode that is formed on the second main surface; and
a conductive member that penetrates through the nitride epitaxial layer and electrically connects the source electrode to the SiC substrate.

9. The nitride semiconductor device according to claim 4, wherein the first nitride semiconductor layer is constituted of a GaN layer and the second nitride semiconductor layer is constituted of an AlGaN layer.

10. The nitride semiconductor device according to claim 5, wherein the first nitride semiconductor layer is constituted of a GaN layer, the second nitride semiconductor layer is constituted of an AlGaN layer, and the semi-insulating nitride layer is constituted of a GaN layer that contains carbon.

11. The nitride semiconductor device according to claim 6, wherein the first nitride semiconductor layer is constituted of a GaN layer, the second nitride semiconductor layer is constituted of an AlGaN layer, the semi-insulating nitride layer is constituted of a GaN layer that contains carbon, and the buffer layer is constituted of a laminated film of an AlN layer formed on the first main surface and an AlGaN layer that is laminated on the AlN layer.

12. The nitride semiconductor device according to claim 6, wherein the first nitride semiconductor layer is constituted of a GaN layer, the second nitride semiconductor layer is constituted of an AlGaN layer, the semi-insulating nitride layer is constituted of a GaN layer that contains carbon, and the buffer layer is constituted of an AlN layer or an AlGaN layer.

13. The nitride semiconductor device according to claim 2, wherein the nitride epitaxial layer comprises:
a first nitride semiconductor layer that constitutes an electron transit layer and
a second nitride semiconductor layer that is disposed on the first nitride semiconductor layer, constitutes an electron supply layer, and is higher in bandgap than the first nitride semiconductor layer.

14. The nitride semiconductor device according to claim 3, wherein the nitride epitaxial layer comprises:
a first nitride semiconductor layer that constitutes an electron transit layer and
a second nitride semiconductor layer that is disposed on the first nitride semiconductor layer, constitutes an electron supply layer, and is higher in bandgap than the first nitride semiconductor layer.

15. The nitride semiconductor device according to claim 13, comprising: a semi-insulating nitride layer that is disposed between the SiC substrate and the first nitride semiconductor layer and with which an acceptor concentration is higher than a donor concentration.

16. The nitride semiconductor device according to claim 14, comprising: a semi-insulating nitride layer that is disposed between the SiC substrate and the first nitride semiconductor layer and with which an acceptor concentration is higher than a donor concentration.

17. The nitride semiconductor device according to claim 15, comprising: a buffer layer that is disposed between the SiC substrate and the semi-insulating nitride layer and is constituted of a nitride semiconductor.

18. The nitride semiconductor device according to claim 16, comprising: a buffer layer that is disposed between the SiC substrate and the semi-insulating nitride layer and is constituted of a nitride semiconductor.
